(19) United States
(12) Patent Application Publication
(10) Pub. No.: US 2003/0057529 A1
(43) Pub. Date: Mar. 27, 2003

(54) Package for a discrete device and manufacturing method of the same

(75) Inventor: Chikao Ikenaga, Tokyo-To (JP)

Correspondence Address: PARKHURST & WENDEL, L.L.P., 1421 PRINCE STREET, SUITE 210, ALEXANDRIA, VA, 22314-2805, US

(73) Assignee: Dai Nippon Printing Co., Ltd., Shinjuku-Ku (JP)

(21) Appl. No.: 10/226,239

(22) Filed: Aug. 23, 2002

(30) Foreign Application Priority Data
Aug. 28, 2001 (JP) 2001-257688

(51) Int. Cl. H01L 23/495

(52) U.S. Cl. 257/666

(57) ABSTRACT

A lead frame having a terminal portion 12 for connection which is connected thereto by a lead portion 21 is prepared, and a heat-resistant tape 24 for preventing a burr of resin is attached to a back surface of the lead frame 20. A discrete device 11 having a back surface thereof metallized is loaded on the heat-resistant tape 24 from a front surface thereof. An electrode 11a disposed on an upper surface of the discrete device 11 and the terminal portion 12 of the lead frame 20 are wire-bonded by a wire 13. An outer peripheral region surrounding the discrete device 11, the terminal portion 12 of the lead frame 20 and the wire 13 is encapsulated by a molding resin 14. Then, the heat-resistant tape 24 is released and the molding resin 14 is separated into pieces by dicing.

### FIELD OF THE INVENTION

The present invention relates to a technical field of a so-called discrete device such as diode, transistor and capacitor. More particularly, it pertains to a package encapsulating such a discrete device and a method for manufacturing the same.

### RELATED ART

Electronic instruments have recently been reduced in size and weight, and therefore various electronic components used in these instruments also have to be miniaturized. The same requirement is true with packages for discrete devices (mono-functional devices such as diodes, transistors and capacitors). A backside packaging type has been proposed for the miniaturization thereof. The backside packaging type is assembled to encapsulate components by using a ceramic substrate. However, the disadvantage of this type of package has is that the ceramic member is expensive, and so the package does not match market prices.

On the other hand, FIG. 4 shows a proposed discrete device adopting an entire encapsulating type of package structure such as QFN (Quad Flat Non-Leaded Package), and having the same structure as a package of a ceramic backside packaging type. FIG. 4 shows a package for a discrete device when being manufactured, in which reference numbers 1a, 1, and 2 indicate a lead frame, a terminal portion of the lead frame, and a die pad, respectively. Reference number 3 in FIG. 4 indicates a tape for preventing a resin burr, which is attached to a back surface of the lead frame; reference number 4 refers to a discrete device which is loaded on the die pad 2; reference number 5 refers to a wire which electronically connects an electrode disposed on an upper surface of the discrete device 4 and the terminal portion 1 of the lead frame 1a; and reference number 6 refers to a molding resin which entirely encapsulates an outer peripheral region of the discrete device 4, the terminal portion 1 of the lead frame 1a, and the wire 5. As illustrated, after the components are entirely encapsulated by the molding resin 6, the tape 3 for preventing a resin burr is removed and replaced by a dicing tape, whereby the molding resin 6 is separated into pieces by dicing.

Since the package for a discrete device having such a structure as described above has the die pad 2 residing in the lead frame 1a, the thickness of the package is the sum of the thickness of the substrate of the lead frame 1a, the thickness of the discrete device 4, the height of the wire 5, and the thickness of the resin from the top of the wire 5. Thus, it is difficult to make the thickness of the package less than 0.5 mm. As a specific use, the discrete device 4 may be loaded in a module such as a quartz resonator. In this case, a package having a thickness less than 0.4 mm is currently needed to reduce the thickness of the module. However, the above package for a discrete device cannot satisfy this requirement, and other suitable member are not currently found.

As for a device such as a diode, transistor and capacitor, which are discrete devices, the back surface of the discrete device 4 is metallized and die-bonded to the lead frame 1a by an Au—Si eutectic bonding at a high temperature of 430° C. However, when adopting the entire encapsulating type structure QFN, problems arise. For example, die-bonding cannot suitably be achieved because the heat resistance of the tape for preventing a resin burr is low, or certain devices cannot satisfy an electronic property with an ordinary conducting paste so that a specific conducting paste must be developed in order to carry out die-bonding at a low temperature.

### SUMMARY OF THE INVENTION

The present invention is made in consideration of the above disadvantages, and an object thereof is to provide a package for a discrete device in which a price of members can be kept down and a total thickness of the package can be reduced as much as possible.

A package for a discrete device according to the present invention comprises a lead frame including a terminal portion; a discrete device including an electrode, the discrete device disposed away from the terminal portion of the lead frame; a wire connecting the terminal portion of the lead frame and the electrode of the discrete device; and a molding resin encapsulating an outer peripheral region surrounding the terminal portion of the lead frame, the discrete device and the wire, wherein the terminal portion of the lead frame and the discrete device having the respective back surfaces exposed outward.

In the package for a discrete device, the back surface of the discrete device may be metallized.

In the package for a discrete device, the electrode may be disposed on an upper surface of the discrete device.

A manufacturing method for a package for a discrete device according to the present invention comprises the steps of preparing a lead frame including a terminal portion; attaching a heat-resistant tape for preventing a burr of resin to a back surface of the lead frame; mounting a discrete device including an electrode on the heat-resistant tape from a front side thereof; connecting the terminal portion of the lead frame and the electrode of the discrete device by a wire; encapsulating an outer peripheral region surrounding the terminal portion of the lead frame, the discrete device and the wire by a molding resin; and releasing the heat-resistant tape from the molding resin, the terminal portion of the lead frame and the discrete device to expose the respective back surfaces of the terminal portion of the lead frame and the discrete device outward.

In the manufacturing method for a package for a discrete device, the method may further comprise the step of separating the molding resin into pieces by dicing after the heat-resistant tape is released.

### BRIEF DESCRIPTION OF THE DRAWINGS

FIGS. 1A to 1D are views respectively showing a step of manufacturing procedure of a package for a discrete device according to the present invention;

FIG. 2 is a cross-sectional view showing an example of a package for a discrete device according to the present invention;

FIG. 3A is an overall view showing a lead frame which is used for manufacturing a package for a discrete device shown in FIG. 2;

FIG. 3B is an enlarged view of a portion indicated by a letter “P” shown in FIG. 3A; and

FIG. 4 is a cross-sectional view showing a conventional package for a discrete device.

### DETAILED DESCRIPTION OF THE INVENTION

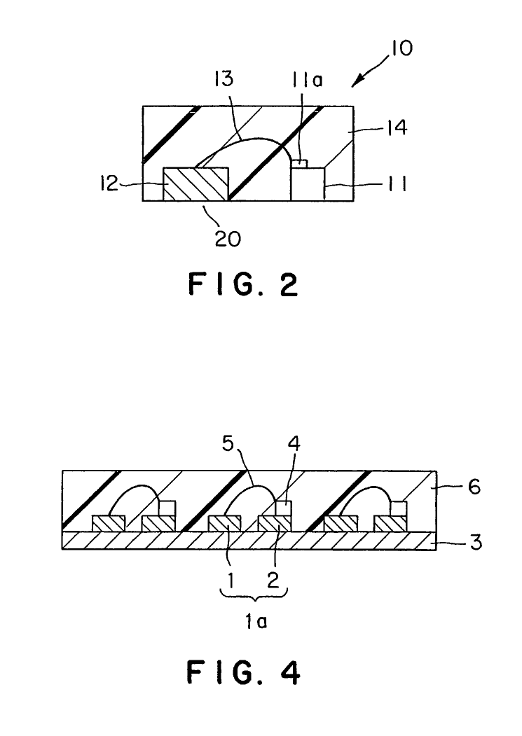

An embodiment of the present invention is described with reference to the drawings. FIG. 2 is a cross-sectional view showing an example of a package for a discrete device according to the present invention, in which a package for a discrete device 10 includes a lead frame 20 having terminal portions 12 for connection, discrete devices 11 each having a back surface thereof metallized, and wires 13 electronically connecting electrodes 11a disposed on upper surfaces of the discrete devices 11 and the terminal portions 12 of the lead frame 20. An outer peripheral region surrounding the wires 13, the discrete devices 11 and the terminal portions 12 of the lead frame 20 is encapsulated by a molding resin 14, with the back surfaces of the discrete devices 11 and the terminal portions 12 of the lead frame 20 being respectively exposed.

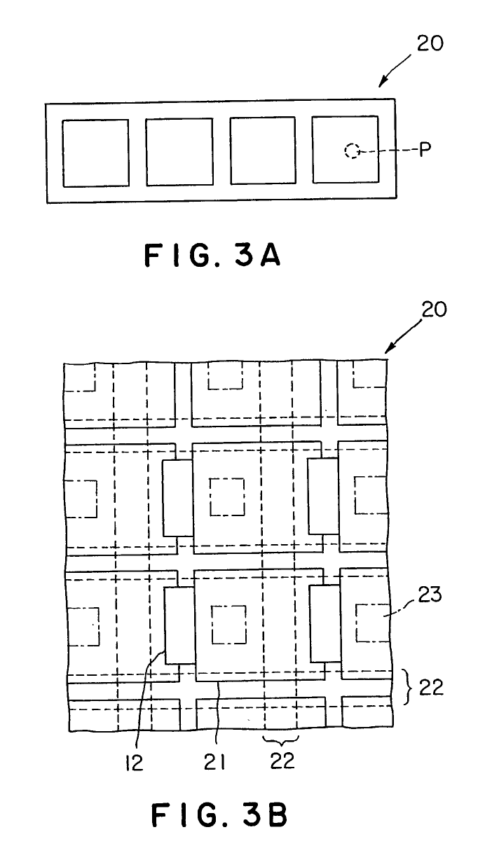

FIG. 3A is an overall view showing a lead frame which is used for manufacturing the package for a discrete device 10 shown in FIG. 2, and FIG. 3B is an enlarged view of a portion indicated by a letter “P” shown in FIG. 3A. The lead frame 20 has terminal portions 12 for connection which are connected to each other by a lead portion 21. The lead frame 20 has generally a flat and lattice-like shape. Each terminal portion 12 has a thickness of a substrate of the lead frame 20 of itself, while the lead portion 21 is half-etched and is smaller than the terminal portion 12 in thickness. The thickness of the lead portion 21 is reduced by half-etching so as to prevent a cut portion of the lead frame from forming a metal burr when the molding resin 14 is separated into pieces by dicing. In FIG. 3B, portions 22 indicated by dotted lines are a dicing portions, and portions 23 indicated by chine lines are positions on which the discrete devices 11 are to be mounted.

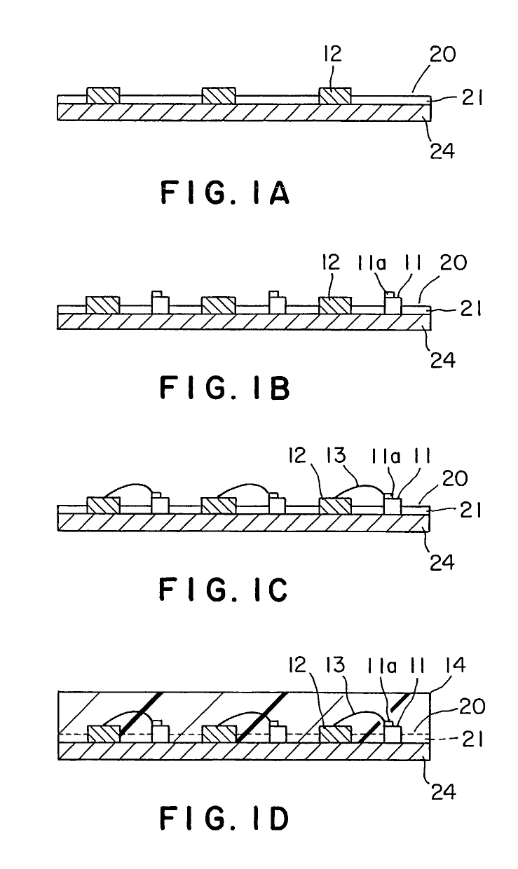

Referring to FIGS. 1A to 1D, a manufacturing procedure of the package for manufacturing a discrete device 10 (FIG. 2) by using a lead frame 20, is described. As shown in FIG. 1A, a lead frame 20 having terminal portions 12 and a lead portion 21 is prepared. A heat-resistant tape 24 for preventing a resin burr is attached to a back surface of the lead frame 20. As shown in FIG. 1B, a discrete device 11 having a back surface thereof metallized is mounted on the heat-resistant tape 24 at a predetermined position from a front side of the heat-resistant tape 24. As shown in FIG. 1C, electrodes 11a disposed on upper surfaces of the discrete devices 11 and the terminal portions 12 of the lead frame 20 are wire-bonded by means of wires 13. Then, as shown in FIG. 1D, an outer peripheral region of the discrete devices 11, the terminal portions 12 of the lead frame 20 and the wires 13 is entirely encapsulated by a molding resin 14. After that, the heat-resistant tape 24 is released, and then a tape for dicing is attached to the mold resin 14, whereby the molding resin 14 is separated into pieces by dicing. The package for a discrete device 10 shown in FIG. 2 is thus obtained.

(Embodiment)

A concrete embodiment is described hereafter.

A package of two-pin backside packaging type having diode devices encapsulated by a molding resin was manufactured in this embodiment.

A lead frame 20 of an entire encapsulating type having no die pad, as shown in FIGS. 3A and 3B, was prepared by using a copper alloy with a thickness of 0.15 mm (manufactured by Furukawa Electric Co., Ltd. “EFTEC64T”). A heat-resistant tape 24 (manufactured by Nitto Denko Corporation “TRM6250”) for preventing a resin burr was attached to a back surface of the lead frame 20. Diode devices (discrete devices) 11 having back surfaces thereof metallized were directly mounted on the heat-resistant tape 24. Portions where the diode devices 11 were to be mounted, were indicated by chain lines in FIG. 3B. A heat treatment or others were not conducted then.

After a wire-bonding step with wires 13 and an encapsulating step with a molding resin 14, the heat-resistant tape 24 for preventing a resin burr was released. A tape for dicing was attached to the mold resin 14 for carrying out a dicing. After that, the mold resin 14 was separated into pieces by dicing to obtain encapsulated diode devices 11. Then, the diode devices 11 were entirely checked. Then, the tape was made to be non-adhesive by a ultraviolet irradiation whereby the encapsulated diode devices 11 were released from the tape. A diode package 10 obtained as above had a thickness of 0.4 mm.

While the embodiment of the present invention has been described in detail, a package for a discrete device and a manufacturing method thereof according to the present invention are not limited thereto, and it is a matter of course that various changes and modifications are possible without departing from the scope of the invention.

A package for a discrete device according to the present invention comprises a lead frame including a terminal portion, a discrete device including an electrode, the discrete device disposed away from the terminal portion of the lead frame, a wire connecting the terminal portion of the lead frame and the electrode of the discrete device, and a molding resin encapsulating an outer peripheral region surrounding the terminal portion of the lead frame, the discrete device and the wire, with the respective back surfaces of the terminal portion of the lead frame and the discrete device being exposed outward. Accordingly, a die pad is not present under the discrete device so that a total thickness of the package can be reduced as much as possible.

Further, an entire encapsulating QFN structure can be obtained without conducting a die-bonding of a high temperature when being manufactured, whereby a price of members can be kept down as compared with a conventional package structure having a ceramic substrate.

What is claimed is:

1. A package for a discrete device comprising:
a lead frame including a terminal portion;
a discrete device including an electrode, the discrete device disposed away from the terminal portion of the lead frame;
a wire connecting the terminal portion of the lead frame and the electrode of the discrete device; and
a molding resin encapsulating an outer peripheral region surrounding the terminal portion of the lead frame, the discrete device and the wire,
wherein the terminal portion of the lead frame and the discrete device have the respective back surfaces exposed outward.

2. The package for a discrete device according to claim 1 ,wherein
the back surface of the discrete device is metallized.

3. The package for a discrete device according to claim 1, wherein
the electrode is disposed on an upper surface of the discrete device.

4. A manufacturing method for a package for a discrete device, comprising the steps of:
preparing a lead frame including a terminal portion;
attaching a heat-resistant tape for preventing a burr of resin to a back surface of the lead frame;
mounting a discrete device including an electrode on the heat-resistant tape from a front side thereof;
connecting the terminal portion of the lead frame and the electrode of the discrete device by a wire;
encapsulating an outer peripheral region surrounding the terminal portion of the lead frame, the discrete device and the wire by a molding resin; and
releasing the heat-resistant tape from the molding resin, the terminal portion of the lead frame and the discrete device to expose the respective back surfaces of the terminal portion of the lead frame and the discrete device outward.

5. The manufacturing method for a package for a discrete device according to claim 4,
further comprising the step of separating the molding resin into pieces by dicing after the heat-resistant tape is released.
